(19) United States
(12) Patent Application Publication
(10) Pub. No.: US 2025/0157792 A1
(43) Pub. Date: May 15, 2025

(54) Symmetrical Process Reactor

(71) Applicant: Stephan Wege, Bannewitz-Cunnersdorf (DE)

(72) Inventor: Stephan Wege, Bannewitz-Cunnersdorf (DE)

(21) Appl. No.: 18/835,867

(22) PCT Filed: Jan. 27, 2023
(86) PCT No.: PCT/DE2023/100062

§ 371 Date: Aug. 5, 2024

(30) Foreign Application Priority Data
Feb. 7, 2022 (DE) 10 2022 102 768.6

(51) Int. Cl. H01J 37/32

(52) U.S. Cl. CPC H01J 37/3244; H01J 2237/334

(57) ABSTRACT

A process reactor (10) for plasma etching with atomic precision (ALE) of a substrate (12) to be processed and/or for plasma assisted deposition of atomic layers on the substrate (12) includes a reaction chamber (16) in which a table (18) and/or a holder for the substrate (12) is provided. By means of a gas supply (31), the substrate (12) is uniformly covered with gas in the reaction chamber (12). A pump (60) is used to evacuate the reaction chamber (16). A plasma generator (46) for generating a plasma (10) in the reaction chamber (16) are also provided.

### CROSS-REFERENCE TO RELATED APPLICATION

This application is a national stage application, filed under 35 U.S.C. § 371, of International Patent Application PCT/DE2023/100062, filed on Jan. 27, 2023, which claims the benefit of German Patent Application DE 10 2022 102 768.6, filed on Feb. 7, 2022.

### TECHNICAL FIELD

The disclosure relates to a process reactor for plasma etching with atomic precision (ALE) of a substrate to be processed and/or for plasma assisted deposition of atomic layers (PEALD) on the substrate.

### BACKGROUND

Process reactors are used in plasma etching (ALE) or plasma assisted deposition (PEALD) of individual atomic layers on a substrate. During deposition, individual atomic layers are applied to the substrate, such as a semiconductor, using the ALD (=Atomic Layer Deposition) or PEALD (Plasma Enhanced ALD) method. This allows for the creation of extremely small structures or doping on a substrate, as required in industrial chip manufacturing.

In the PEALD process, the substrate reacts sequentially with appropriate reactants, also called “precursors”. The sequential process allows precise control of the atomic layer thickness.

The PEALD process can be described as follows: First, the cleaned surface of the substrate is exposed to a first reactant (usually without plasma) in the reaction chamber of the process reactor. The substrate is often a disc-shaped semiconductor, also called a wafer. It is necessary that the adsorption on the surface is controlled by a self-limiting process. The choice of the appropriate precursor (reactant) is crucial to ensure that no more than one monolayer of the first reactant is adsorbed, regardless of the amount of gas supplied. The residues of the first reactant are then flushed or pumped out of the reaction chamber of the process reactor. This prevents a gas phase reaction with a second reactant. The latter is then passed over the substrate surface and caused to react by thermal energy in classical ALD. Subsequently, a so-called purge cycle is usually required in the process reactor.

The reactivity of the reactants with the substrate can be significantly enhanced by using a plasma. The plasma is generated, for example, by the interaction of an alternating electric field in a capacitively coupled system.

In this process, it is desirable that the reactants can react with the substrate as uniformly as possible in both time and space. PEALD system technology is inherently complex because the gas handling and other flow dynamic systems must also correspond to the uniform coupling of RF power (RF=high frequency).

Atomic layer etching (ALE) is a technique where a sequence between self-limiting chemical modification steps, which affect only the topmost atomic layers of the substrate, and etching steps, which remove only the chemically modified areas, allows the removal of individual atomic layers. This process requires complex gas handling for etching rates of one atomic layer.

For PEALD deposition and ALE etching in a process reactor, flow dynamics are an important parameter, especially for the required uniformity. Thus, the gas must be introduced into the reaction chamber of the process reactor as uniformly and symmetrically as possible.

DE 10 2016 108 845 A1 discloses a gas injector for such ALD, PEALD, or ALE process reactors. The gas injector is designed as a ring-shaped base body, with gas inlet nozzles arranged symmetrically pointing to the center in the base body. The inlet nozzles are individually or in groups supplied with gas via gas supplies. At least one bypass is provided to uniformly bring the gas to the inlet nozzles. This brings the reaction area, in which the substrate is located, uniformly into contact with the reactants for reaction in both time and space.

EP 0552 491 B1 relates to a plasma etching process using high-frequency plasma processing reactors. A plasma reactor is described that uses a high-frequency (HF) energy source to electromagnetically couple the associated electromagnetic HF wave with the plasma, with a silicon source in contact with the plasma. Processes are conducted in such a reactor.

DE 10 2020 107 215 A1 describes a method for processing a semiconductor wafer. The method includes loading a semiconductor wafer onto an upper surface of a wafer holding device. The method also includes supplying a gaseous material between the semiconductor wafer and the upper surface of the wafer holding device through a first and second gas inlet openings located below a fan-shaped section of the upper surface. Additionally, the method includes supplying a fluid medium into a fluid inlet opening of the wafer holding device and guiding the fluid medium from the fluid inlet opening through several arcuate channels located below the fan-shaped section of the upper surface. Furthermore, the method includes supplying a plasma gas over the semiconductor wafer.

DE 10 2019 001 615 A1 introduces a plasma assisted CVD method in which the energy for generating the plasma is not coupled into the CVD reactor by electromagnetic radiation but is released by an explosion, ultimately creating the plasma. Within the explosion zone, a plasma with layer-forming and growth-promoting reaction species is created, which hit the substrate surface through the shock front spreading from the explosion site, where the thin film to be deposited forms. The advantage of such a process is layer deposition within a very short period. However, uniform deposition on a substrate is not easily achievable with this method.

DE 11 2014 005 386 B4 refers to a gas deposition system designed to conduct plasma-activated atomic layer deposition (PEALD) gas deposition cycles, used to deposit thin film material layers on exposed surfaces of a solid-state substrate. The PEALD system particularly includes a reaction chamber, a main vacuum pump to establish a first vacuum pressure in the reaction chamber during non-plasma precursor deposition cycles, and a second vacuum pump to establish a second lower vacuum pressure in the reaction chamber during plasma precursor deposition cycles.

WO 2007/042017 A1 relates to a device and a method for plasma treatment of objects. The device includes a plasma chamber in which at least one electrode is arranged as an object carrier. Furthermore, at least one wall area of the plasma chamber and/or at least one component arranged in the plasma chamber forms a counter-electrode. Using a high-frequency unit, plasma can be generated in the plasma chamber by applying a high-frequency alternating voltage between the electrode and the counter-electrode. The plasma chamber is divided into at least two partial volumes by a separating device, one of which includes the electrode and reactive gas and the other includes the counter-electrode's active area with inert gas. The separating device is designed to allow electron exchange required for plasma generation between the partial volumes and act as a diffusion barrier for the reactive gas. With this device and method, deposits caused by plasma treatment on the counter-electrode can be reduced.

The known ALD, PEALD, and ALE systems have the disadvantage that the substrates to be processed do not uniformly come into contact with their reactant across their surface. This is due to an unequal distribution of the reacting gas in the reaction chamber.

### SUMMARY

The present application presents a process reactor that enables uniform covering of the substrate surface with the respective reactant or precursor.

This is achieved by a process reactor for plasma etching with atomic precision (ALE) of a substrate to be processed and/or for plasma assisted deposition of atomic layers (PEALD) on the substrate, comprising:
a) a reaction chamber,
b) a table and/or holder for the substrate in the reaction chamber,
c) a gas supply, which uniformly covers the substrate with gas in the reaction chamber,
d) a pump for evacuating the reaction chamber,
e) a plasma generator for generating a plasma in the reaction chamber, and.
f) the reaction chamber is designed to be rotationally symmetrical, with the pump being centrally symmetrically arranged below the table and/or the holder in the reaction chamber.

The known ALD, PEALD, and ALE systems have attempted to achieve uniformity of the gas as a reactant by optimizing the gas inlet. The disclosure is based on the principle of considering not only the gas entry into the reaction chamber but also the gas exit from the reaction chamber. Surprisingly, it has been found that the flow conditions in the process chamber also significantly depend on the design of the reaction chamber and the position of the evacuating pump. The interaction of the rotational symmetry of the reaction chamber and the centrally arranged pump ensures uniform flow in the area of the substrate surface during the operation of the system. The pump is arranged below the table and/or the holder. This allows uniform flow to be ensured even during evacuation in the reaction chamber. Numerous processes or reactions can be accelerated by the plasma. The plasma should also have optimized uniformity to obtain a uniform and thus well-reproducible process.

An advantageous embodiment of the process reactor for plasma etching with atomic precision (ALE) of a substrate to be processed and/or for plasma assisted deposition of atomic layers on the substrate is that at least one tubular profile body is provided for positioning the table and/or the holder in the reaction chamber above the pump. Uniform flow within the reaction chamber is extremely important so that the reactant can react uniformly with the substrate over its entire surface. The tubular profile bodies form a shape that allows optimized flow. The table or holder is located above the pump, which is required for evacuating the reaction chamber.

In a preferred embodiment of the process reactor for plasma etching with atomic precision (ALE) of a substrate to be processed and/or for plasma assisted deposition of atomic layers on the substrate, at least one supply line is guided from outside the reaction chamber to the table and/or the holder through the tubular profile body. Supply or discharge lines are required to supply resources or remove residues at the table or substrate. They previously disturbed the uniform flow. The supply lines are therefore laid in the tubular profile body and thus do not create additional unwanted turbulence in the uniform flow.

A further preferred embodiment of the process reactor results from the fact that a through passage, in particular for the supply line, is provided in the connection region of the tubular profile body to the table and/or the holder. At least one passage in the table or holder is provided to guide the supply line over the table or holder. This measure ensures that the lines, e.g. for gas, cooling or sensors, are not routed around the table or holder, as this would only lead to unwanted turbulence.

In a preferred embodiment of the process reactor for plasma etching with atomic precision (ALE) of a substrate to be processed and/or for plasma assisted deposition of atomic layers on the substrate, at least six tubular profile bodies are radially symmetrically arranged for positioning the table and/or the holder in the reaction chamber.

A particularly advantageous embodiment of the process reactor is also achieved in that the table and/or the holder in the reaction chamber is designed to be height adjustable. This allows the substrate to be brought into an optimal position for gas supply. For different substrates with various layer thicknesses, the distances to the gas supply arranged above the substrate can be optimally balanced.

In a further advantageous embodiment of the process reactor, the substrate to be processed is arranged centrally in the rotationally symmetrical reaction chamber. This measure serves to align the flow conditions of a gas as a reactant with the rotationally symmetrical reaction chamber. This improves the uniformity of the reactant in the area of the substrate surface.

An advantageous variant of the process reactor results from the fact that the gas supply consists of a gas injector which includes a pipe ring with radially symmetrical nozzles pointing towards the central axis, in which the substrate to be processed is centrally arranged.

In an advantageous embodiment of the process reactor for plasma etching with atomic precision of a substrate to be processed and/or for plasma assisted deposition of atomic layers on the substrate, the pipe ring has at least one bypass for the uniform supply of the nozzles. The flow conditions of the reactant also depend on the gas uniformly exiting from the nozzles of the gas injector. In the area of the nozzles of the gas injector, turbulence occurs in the pipeline ring. This can cause the gas pressures at the nozzles to be different. To supply the nozzles with as uniform gas pressures as possible, at least one bypass channel is provided.

A further advantageous embodiment of the process reactor for plasma etching with atomic precision of a substrate to be processed and/or for plasma assisted deposition of atomic layers on the substrate results from the fact that a back pressure generator is provided. The back pressure generator is used to create back pressure with the reacting gas. This increases the uniformity of the reactant in the area of the substrate surface. The back pressure generator can be a sieve-shaped metal ring, which as a side effect keeps the expansion of the plasma only in the reaction area of the reaction chamber. Thus, it also serves as a plasma limiter.

A preferred and advantageous embodiment of the process reactor for plasma etching with atomic precision (ALE) of a substrate to be processed and/or for plasma assisted deposition of atomic layers on the substrate is achieved by providing a vacuum lock for introducing the substrate. The vacuum lock allows the substrate to be introduced into the reaction chamber without having to evacuate the entire chamber for each process. The vacuum lock can be designed so that both the table or holder and the substrate can be guided through the vacuum lock to load and unload the reaction chamber. The vacuum lock should be covered in the reaction chamber, for example, with a flap or a slide, so that no turbulence occurs in the reaction chamber at the opening during operation. This further supports the uniformity of the gas flow.

Other embodiments and advantages arise from the subject matter of the dependent claims and the drawings with their corresponding descriptions. Exemplary embodiments are further explained below with reference to the attached drawings. Spatial relative terms, such as “below,” “under,” “lower,” “above,” “upper,” and the like, may also be used in the present text to simplify the description, to describe the relationship of an element or structural element to one or more other elements or structural elements, as illustrated in the figures. The spatial relative terms are intended to include other orientations of the device during use or operation, in addition to the orientation shown in the figures. The device can also be oriented differently (rotated 90 degrees or otherwise oriented), and the spatial relative descriptors used in the present text can be interpreted accordingly.

The invention should not be limited solely to these listed exemplary embodiments. They are merely intended to further explain the invention. Furthermore, the content of the cited publications is included in the disclosure of the present application.

### BRIEF DESCRIPTION OF THE DRAWINGS

FIG. 1 shows a schematic principle sketch of a vertical section of a process reactor for depositing atomic layers on a substrate.

FIG. 2 shows a schematic principle sketch of a horizontal section through the process reactor as shown in FIG. 1.

### DETAILED DESCRIPTION

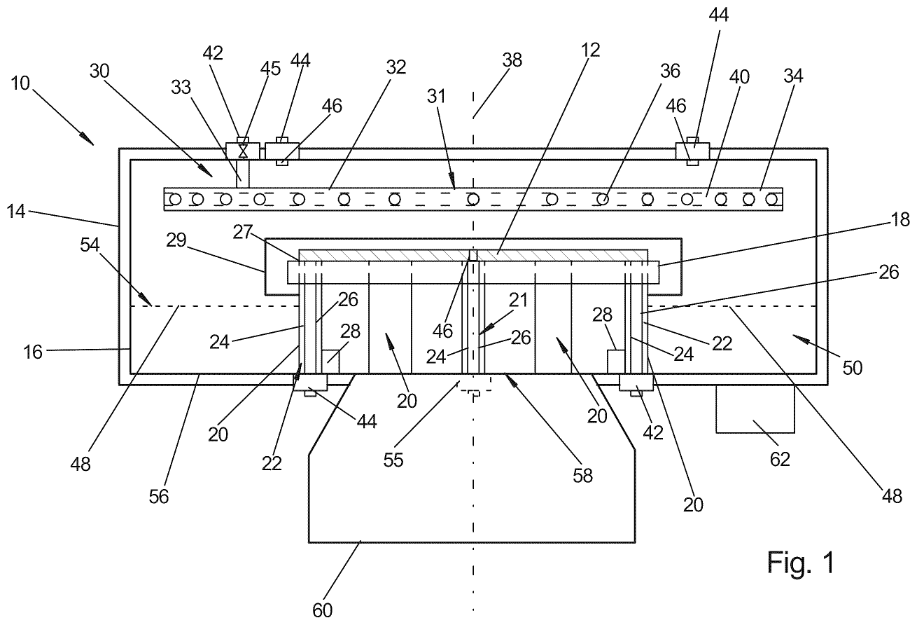

In FIG. 1, a schematic principle sketch of the vertical section of a process reactor 10 for plasma etching with atomic precision (ALE) of a substrate 12 and/or for plasma assisted deposition of atomic layers on the substrate 12 is shown. The process reactor 10 in this embodiment comprises a protective housing 14, in which a reaction chamber 16 is provided. While the protective housing 14 can have almost any geometric shape as a housing body, the reaction chamber 16 is designed to be rotationally symmetrical.

In the present embodiment, the reaction chamber 16 is essentially cylindrical. Other rotationally symmetrical geometries of the reaction chamber 16 are also conceivable, such as a cone-shaped or spherical reaction chamber 16. The substrate 12 is centrally held on a table 18 in the reaction chamber 16. The table 18 is supported by six tubular profile bodies 20.

The tubular profile bodies 20 are hollow inside, creating a cavity 22. Through the cavity 22 of the tubular profile bodies 20, supply and control lines 21, including supply lines 24 and discharge lines 26, are guided from the reaction chamber 16. The supply lines 24 and discharge lines 26 are, for example, necessary electrical lines, liquid or gas lines. These supply lines 21 are guided through passages 27 in the table 18. In this way, resources can be centrally and symmetrically supplied to the substrate 12 from outside the reaction chamber 16. The tubular profile bodies 20 are height adjustable. This is achieved by a telescopic structure of the tubular profile bodies 20, which can change their length by a drive 28.

The substrate 12 is introduced into the reaction chamber 16 for processing through a vacuum lock 29, and centrally positioned and fixed on the table 18, also called “chuck.” The processed substrate 12 is also removed from the reaction chamber 16 through the vacuum lock 28.

In the upper area 30 of the process reactor's 10 reaction chamber 16, a gas supply 31 is provided. The gas supply 31 is designed as a gas injector 32. From outside the reaction chamber 16, a gas or gas mixture is supplied to the gas injector 32 through a gas line 33. The gas injector 32 consists of a pipe ring 34, on which numerous Laval nozzles 36 are arranged. The center of the ring-shaped gas injector 32 lies on a central axis 38 of the reaction chamber 16. The Laval nozzles 36 are arranged radially symmetrical around the central axis 38. In this embodiment, the Laval nozzles 36 point to the central axis 38 of the reaction chamber 16. To create a uniform and symmetrical distribution of the reaction gas at the Laval nozzles 36, at least one bypass 40 to the pipe ring 34 is provided.

Connections 42, 44 serve to connect the gas line 33, such as for helium, and electrical supply and control lines 21 to the process reactor 10. The amount of gas supplied to the gas injector 32 can be controlled by an adjustable control valve 45. Electrodes 46 are supplied with high-frequency high voltage for generating a plasma via electrical supply lines 24. The reactivity of the reaction partners with the substrate 12 is significantly increased when plasma is used. The plasma is generated by igniting a gas discharge. A sequential sequence is achieved by pulsing the plasma power.

A ring-shaped back pressure generator 48 is provided in the lower area 50, below the table 18. The back pressure generator 48 is a ring sieve 52, understood as a grounded metal ring with numerous fine mesh bores 54 through which a gas can be evacuated. The back pressure generator 48 serves as a back pressure generator for the gas in the reaction chamber 16 and simultaneously limits the expansion of the plasma generated in the reaction chamber 16. Thus, the back pressure generator 48 also acts as a plasma limiter. The back pressure generator 48 also largely decouples the lower area 50 from the upper area 30 in terms of flow dynamics. The electrode 46 is supplied with high-frequency high voltage through connection 55.

The reaction chamber 16 has a central opening 58 at its bottom 56. A turbo pump 60 is flanged centrally symmetrically to this central opening 58. The turbo pump's 60 power is controlled by a processor-controlled control unit 62. The turbo pump 60 serves to evacuate the reaction chamber 16. The turbo pump 60 ensures that the reaction chamber 16 operates permanently in the low-pressure range.

The rotationally symmetrical reaction chamber 16 and the corresponding symmetrical arrangements of the components for gas supply and gas evacuation as reaction partners for the substrate 12 allow for an extremely uniform flow distribution in the area of the centrally symmetrical substrate 12. This desired uniform distribution results in an equally uniform reaction of the gas as a reactant with the substrate 12.

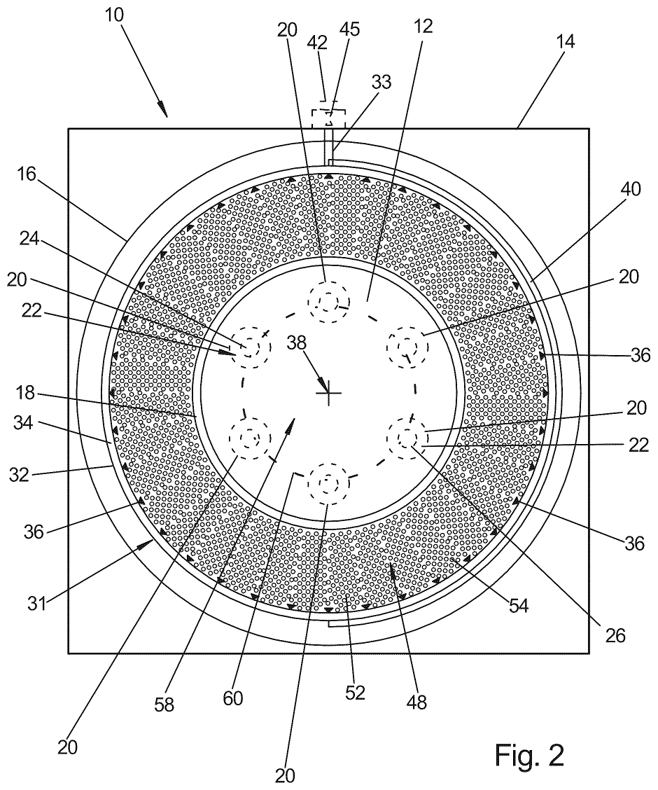

FIG. 2 shows a schematic principle sketch of a horizontal section through the process reactor 10 as shown in FIG. 1. Where the components of the two figures correspond, the same reference numerals are used. As clearly shown in this illustration of FIG. 2, the components are arranged rotationally symmetrically around the central axis 38. The reaction chamber 16 is provided in the protective housing 14.

In the reaction chamber 16, the gas injector 32 is centrally arranged around the axis 38. The Laval nozzles 36 are provided on the pipe ring 34. Some of the Laval nozzles 36 are supplied with gas from the pipe ring 34 and others from the bypass 40. In the present embodiment, the gas injector 32 is supplied with a gas or gas mixture as a reaction partner by the single gas supply line 33 connected to the gas connection 42. The amount of gas supplied to the gas injector 32 through the gas connection 42 is regulated by the control valve 45.

The table 18, on which the substrate 12 is fixed, is supported by the six tubular profile bodies 20. Both the table 18 or chuck and the substrate 12 are centrally positioned in the reaction chamber 16 below the gas injector 32. The profile bodies 20 are also arranged radially symmetrical around the axis 38.

Through the profile bodies 20, the supply lines 24 and possibly also discharge lines 26 are guided. The supply lines 24 may include gas lines for transporting helium or electrical lines for supplying the electrode with high voltage. These lines are adequately insulated to prevent electrical discharges due to high voltage. Heater elements not shown are also supplied with voltage through such supply lines 24. The discharge lines 26 can be, for example, signal lines for transmitting signals from sensors not shown or control signals for various components.

In this horizontal sectional view, the mesh structure of the back pressure generator 48 is well visible. The back pressure generator 48 is formed by the grounded metallic ring sieve 52 with its bores 52. The back pressure generator 48 also prevents unwanted plasma expansion. The back pressure created by the back pressure generator 48 for a gas or gas mixture to be evacuated optimizes the uniformity of the flow in the upper area 30. How the flow behaves below the back pressure generator 48 is largely negligible for the reaction of the substrate 12 with a gas as a reaction partner.

The turbo pump 60 evacuates the reaction chamber 16. The centrally symmetrical arrangement of the turbo pump 60 at the bottom 56 of the reaction chamber 16 causes the gas or gas mixture to be symmetrically sucked through the central opening 58 into the turbo pump 60. The radially symmetrical flow paths of the gas or gas mixture are all approximately the same, ensuring optimized uniformity of the flow paths in the area of the substrate 12. The symmetrical flow paths are only achieved through the radially symmetrical arrangements of the components, the rotationally symmetrical reaction chamber 16, and the centrally symmetrical turbo pump 60.

### REFERENCE NUMERAL LIST

10 process reactor
12 substrate
14 protective housing
16 reaction chamber
18 table
20 tubular profile body
21 supply and control Lines
22 cavity
24 supply lines
26 discharge lines
27 culvert
28 drive
29 vacuum lock
30 upper area
31 gas supply
32 gas injector
33 gas line
34 pipe ring
36 Laval nozzle
38 central axis
40 bypass channel
42 gas connection
44 connection
45 adjustable control valve
46 electrodes
48 back pressure generator
50 lower area
52 ring sieve
54 bores
56 bottom
58 central opening
60 turbo pump
62 control unit

1.-11. (canceled)

12. A process reactor (10) for plasma etching with atomic precision of a substrate (12) to be processed and/or for plasma assisted deposition of atomic layers on the substrate (12), comprising:
a reaction chamber (16);
a table (18) and/or a holder for the substrate (12) in the reaction chamber (16);
a gas supply (31) which uniformly covers the substrate (12) with gas in the reaction chamber (12);
a pump (60) for evacuating the reaction chamber (16); and
a plasma generator (46) for generating a plasma in the reaction chamber (16),
wherein the reaction chamber (16) is rotationally symmetrical, with the pump (60) being centrally symmetrically arranged below the table (18) and/or the holder in the reaction chamber (16).

13. The process reactor (10) according to claim 12,
wherein at least one tubular profile body (20) is provided for positioning the table (18) and/or the holder in the reaction chamber (16) above the pump (60).

14. The process reactor (10) according to claim 13,
wherein at least one supply line (21) is guided from outside the reaction chamber (16) through the tubular profile body (20) to the table (18) and/or to the holder.

15. The process reactor (10) according to claim 14,
wherein a through passage (27) for the supply line (21) is provided in a connection region of the tubular profile body (20) to the table (18) and/or the holder.

16. The process reactor (10) according to claim 12,
wherein at least six tubular profile bodies (20) are arranged radially symmetrically for positioning the table (18) and/or the holder in the reaction chamber (16).

17. The process reactor (10) according to claim 12,
wherein the table (18) and/or the holder in the reaction chamber (16) is height-adjustable.

18. The process reactor (10) according to claim 12,
wherein the substrate (12) to be processed is arranged centrally in the rotationally symmetrical reaction chamber (16).

19. The process reactor (10) according to claim 12
wherein the gas supply (31) comprises a gas injector (32) which includes a pipe ring (34) with radially symmetrical nozzles (36) pointing towards a central axis (38), in which the substrate (12) to be processed is arranged centrally.

20. The process reactor (10) according to claim 19,
wherein the pipe ring (34) has at least one bypass (40) for uniform supply of the nozzles (36).

21. The process reactor (10) according to claim 12,
wherein a back pressure generator (48) is provided.

22. The process reactor (10) according to claim 12,
wherein a vacuum lock (29) is provided for introducing the substrate (12).
